(19) United States
(12) Patent Application Publication
(10) Pub. No.: US 2023/0213572 A1
(43) Pub. Date: Jul. 6, 2023

(54) ARRANGEMENT AND METHOD FOR DETECTING ARCS

(71) Applicant: Siemens Aktiengesellschaft, München (DE)

(72) Inventors: Jörg Meyer, Dresden (DE); Peter Schegner, Dresden (DE); Karsten Wenzlaff, Dresden (DE)

(21) Appl. No.: 17/799,736

(22) PCT Filed: Jan. 15, 2021
(86) PCT No.: PCT/EP2021/050828

§ 371 Date: Aug. 15, 2022

(30) Foreign Application Priority Data
Feb. 14, 2020 (DE) 10 2020 201 887.1

(51) Int. Cl. G01R 31/14; G01R 19/165

(52) U.S. Cl. CPC G01R 31/14; G01R 19/16576; H02H 1/0015

(57) ABSTRACT

An arrangement for detecting arcs in a low-voltage circuit has at least one voltage sensor for periodically determining voltage values of the low-voltage circuit and at least one current sensor for periodically determining current values of the low-voltage circuit. A first control unit is connected to the voltage sensor and the current sensor, has a processor, and is configured in such a way that the presence of a switch arc is determined on the basis of the determined voltage values and current values. A switch arc detection signal is output if a switch arc is determined to be present.

The invention relates to an arrangement for detecting arcs in a low-voltage circuit, to a low-voltage circuit breaker for a low-voltage circuit comprising an arrangement for detecting arcs, and to a method for arc detection for a low-voltage circuit.

Low voltage is taken to mean voltages of up to 1000 volts AC voltage or 1500 volts DC voltage. More specifically, low voltage is taken to mean in particular voltages that are greater than extra-low voltage with values of 50 volts AC voltage or 120 volts DC voltage.

Circuit breakers are protective devices which function in a similar manner to a fuse. Circuit breakers monitor the current flowing through them by means of a conductor and interrupt the electric current or energy flow to an energy sink or a load, which is referred to as tripping, if protection parameters such as current limit values or current-time period limit values are exceeded, i.e. if a current value is present for a certain time period. The set current limit values or current-time period limit values are corresponding tripping reasons. The interruption is effected, for example, by means of an interruption unit at the circuit breaker, for example by contacts which are opened.

Particularly for low-voltage circuits, installations or networks, there are different types of circuit breakers depending on the magnitude of the electric current provided in the electrical circuit. Within the meaning of the invention, circuit breaker is taken to mean in particular switches as used in low-voltage installations for currents, in particular rated currents or maximum currents, of 63 to 6300 amperes. More specifically, enclosed circuit breakers are used for currents of 63 to 1600 amperes, in particular of 125 to 630 or 1200 amperes. Exposed circuit breakers are used in particular for currents of 630 to 6300 amperes, more specifically of 1200 to 6300 amperes.

Exposed circuit breakers are also referred to as air circuit breakers, ACB for short, and enclosed circuit breakers are referred to as molded case circuit breakers or compact circuit breakers, MCCB for short.

Within the meaning of invention, circuit breaker is taken to mean in particular circuit breakers with an electronic trip unit, ETU for short, which serves as a control unit.

In low-voltage circuits or low-voltage installations or low-voltage networks, respectively, short circuits are usually associated with the occurrence of arcs, in this case arc faults, such as parallel or serial arc faults. Arc faults are taken to mean arcs as occur in the case of electrical faults in the circuit or in the installation, respectively. By way of example, they may be caused by short circuits or poor connections. Particularly in high-power distribution and switchgear installations, said arc faults, if not switched off fast enough, can lead to catastrophic destruction of operating equipment, installation parts or complete switchgear installations. In order to avoid a relatively lengthy and extensive power supply outage and to reduce injuries to persons and damage in general, it is necessary to detect and quench such arc faults, in particular arc faults of high current intensity or parallel arc faults, in a few milliseconds. Conventional protective systems of power supply installations cannot offer reliable protection under the temporal requirements demanded.

If a current flows in a faulty phase conductor, for example having a reduced cross section, e.g. as a result of pinching, the reduced current-carrying capacity results in impermissible heating and, as a consequence thereof, possibly in the melting of the conductor and a serial arc fault.

If a (near-)short circuit with another phase conductor occurs, this is referred to as a parallel arc fault. Generally, parallel arc faults produce a conductive, faulty connection between conductors or installation parts.

Parallel arc faults may be caused, for example, by aging of the insulation material or the presence of conductive contamination between phase conductors. They may occur between two different phase conductors, between phase conductor (L) and ground conductor (PE) or between phase conductor and neutral conductor (N). In many cases, the parallel arc also arises on account of a serial arc, e.g. as a result of inappropriate work or incorrectly dimensioned contact means.

In low-voltage circuits or low-voltage installations, arcs furthermore occur during electrical switching, in particular between contacts of a switch, such as a circuit breaker. These arcs are referred to as switching arcs (to distinguish them from the arc faults). Said switching arcs occur regularly and do not signify a fault in the low-voltage circuit.

First possibilities for detecting arcs in low-voltage circuits have become available in the meantime. It is thus possible to effect an interruption in the case of a fault. Differentiating an arc fault from a switching arc is a problem in this context since both are based on an arc and thus have similar electrical properties.

In the case of an arc fault, the electrical circuit should be immediately interrupted in order to avoid destruction of an installation.

In the case of a switching arc, interruption of the electrical circuit should not happen, in order to avoid cost-intensive installation outages.

It is an object of the present invention to make it possible to recognize switching arcs.

This object is achieved by means of an arrangement having the features of patent claim 1, a low-voltage circuit breaker as claimed in patent claim 11 or a method having the features of patent claim 12.

The invention proposes an arrangement comprising:
at least one voltage sensor, for periodically determining voltage values of the low-voltage circuit,
at least one current sensor, for periodically determining current values of the low-voltage circuit,
a first control unit which is connected to the voltage and current sensors and which comprises a processor, and which are configured in such a way that the presence of a switching arc is determined from the determined voltage values and current values and a switching arc detection signal is output in the case of a positive switching arc determination.

This has the particular advantage that in the event of a switching arc being detected, an interruption of the electrical circuit can be prevented, and so cost-intensive installation outages are avoided.

Advantageous configurations of the invention are specified in the dependent claims.

In one advantageous configuration of the invention, the determined voltage values and current values are used for determining an exponential function, in particular an approximated exponential function. The switching arc detection signal is output only if the determined exponent of the exponential function lies within a first range.

Exponential function is taken to mean generally an exponential function and specifically the natural exponential function with the Euler number e as the base.

This has the particular advantage that the presence of a switching arc is determined by determining an exponential function in the voltage profile; that is to say that if the voltage has an exponential profile and the exponent of the exponential function lies within the first range, a switching arc detection signal is output. In this regard, a simple criterion for detecting switching arcs is present.

In one advantageous configuration of the invention, a switching arc detection signal is output only if the change in the voltage with respect to time exceeds a first jump limit value.

This has the particular advantage that a further simple criterion for determining a switching arc is present. Particularly the combination of determination of an exponential function and exceedance of the first jump limit value of the change in the voltage with respect to time allows a reliable and dependable switching arc detection.

In one advantageous configuration of the invention, the determination of the exponential function is begun upon the first jump limit value being exceeded.

This has the particular advantage that a further simple and dependable determination of switching arcs is present, in which case (computational) complexity can be dispensed with since the determination of the calculation of the presence of an exponential function in the voltage profile need be begun only upon the jump limit value being exceeded.

In one advantageous configuration of the invention, within a first time window, in particular simultaneously, a voltage value and a current value are determined as a value pair. An arc voltage and the exponent of the exponential function are determined from at least four successively determined value pairs. A switching arc detection signal is output if the arc voltage exceeds an arc voltage limit value and the exponent of the exponential function lies within the first range.

This has the particular advantage that besides the determination of the exponential function, with the exponent lying in the first range, the arc voltage must also exceed a limit value in order to enable a more dependable and clear switching arc detection.

In one advantageous alternative configuration of the invention, the change in the current with respect to time is determined as a change value from the determined current value. The voltage value, the current value and the change value of a time window form a value set. An arc voltage and the exponent are determined from at least four successively determined value sets. A switching arc detection signal is output if the arc voltage exceeds an arc voltage limit value and the exponent lies within the first range.

This has the particular advantage that likewise, besides the determination of the exponential function, with the exponent lying in a range, the arc voltage must also exceed a limit value in order to enable a more dependable and clear switching arc detection. In this case, the calculation can alternatively be effected more accurately by means of an extended value set.

In one advantageous configuration of the invention, a second control unit is provided, which is configured in such a way, or the first control unit is furthermore configured in such a way, that the presence of an arc fault is determined from the voltage values and current values and an arc fault detection signal is output in the case of a positive arc fault determination.

This has the particular advantage that besides the determination of a switching arc, the determination of an arc fault is also carried out. In this regard, a switching arc detection signal and an arc fault detection signal are present, which can be processed further.

In one advantageous configuration of the invention, an interruption unit for interrupting the low-voltage circuit is provided, which is connected to the first and optionally the second control unit,

in that the low-voltage circuit is interrupted in the case of positive determination of an arc fault and negative determination of a switching arc.

This has the particular advantage that the safety of installations is increased and incorrect shutdowns are avoided.

In one advantageous configuration of the invention, an interruption takes place only if a first number of current values exceeds a first current limit value.

This has the particular advantage that an overcurrent release is effected, that is to say that an interruption takes place only if there are actually high currents with a corresponding energy volume and a corresponding destructive power.

In one advantageous configuration of the invention, the low-voltage circuit is a low-voltage AC circuit.

This has the particular advantage that arc faults and switching arcs can be dependably differentiated, particularly in AC circuits.

In one advantageous configuration of the invention, the above arrangement is provided in a low-voltage circuit breaker.

This has the particular advantage that a protective device for overcurrents and short-circuit currents is extended by arc fault detection and shutdown, in which case, according to the invention, switching arcs do not lead to an interruption of the circuit.

Furthermore, the invention analogously claims a method wherein:
voltage values and current values of the low-voltage circuit are determined periodically,
the determined voltage values and current values are used for determining the exponent of an exponential function,
a switching arc detection signal is output only if the exponent within a first range.

In one advantageous configuration of the invention, a switching arc detection signal is output only if (additionally) the change in the voltage with respect to time exceeds a first jump limit value.

In one advantageous configuration of the invention, the determination of the exponent of the exponential function is begun upon the first jump limit value being exceeded.

In one advantageous configuration of the invention, within a first time window, in particular simultaneously, a voltage value and a current value are determined as a value pair. The exponent of the exponential function is determined from at least four successively determined value pairs.

The advantages in respect of the arrangement are analogously applicable to the configurations in respect of the method.

All configurations, both in dependent form referring back to patent claim 1, 11 or 12 and referring back just to individual features or combinations of features of patent claims, bring about a detection or an improvement of the detection of switching arcs or the use thereof for effectively protecting a low-voltage circuit.

The described properties, features and advantages of this invention and the way in which they are achieved will become clearer and more clearly understood in association with the following description of the exemplary embodiments which are explained in greater detail in association with the drawing.

In the associated drawing:

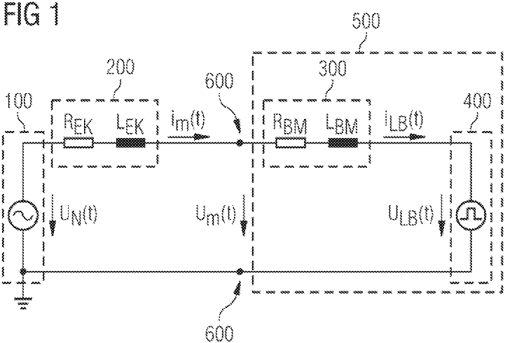

FIG. 1 shows an equivalent circuit diagram of an electrical circuit,

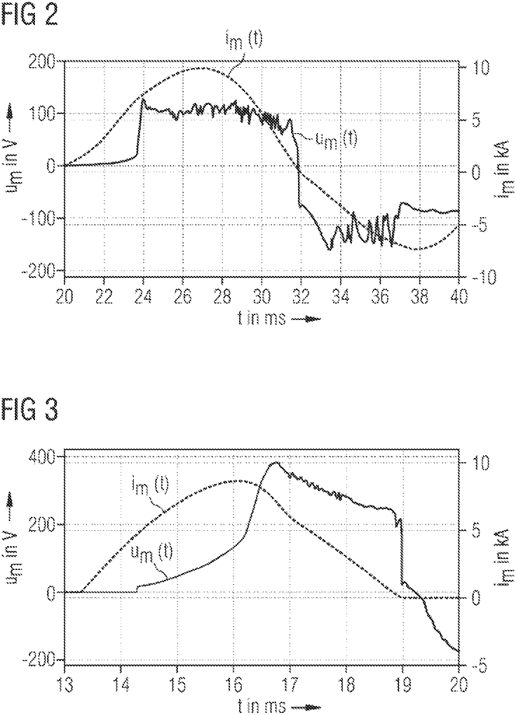

FIG. 2 shows a first diagram of the temporal voltage and current profiles in the case of an arc fault ignition,

FIG. 3 shows a first diagram of the temporal voltage and current profiles in the case of a switching arc ignition,

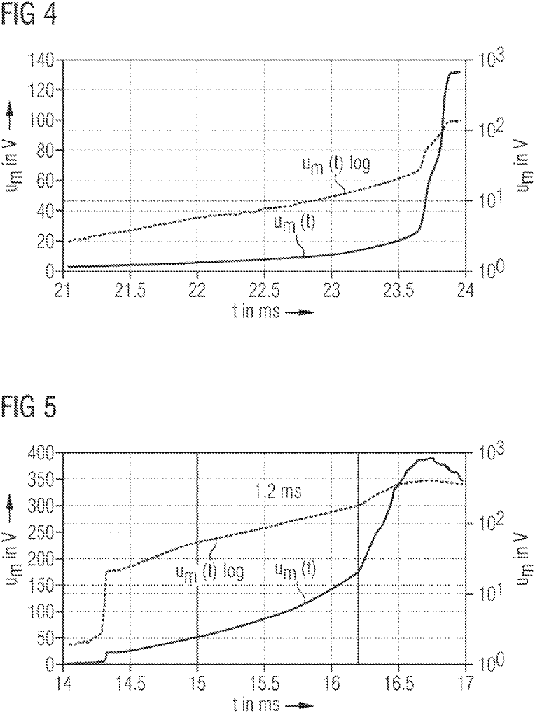

FIG. 4 shows a semilogarithmic diagram of the temporal voltage profile in the case of an arc fault ignition,

FIG. 5 shows a semilogarithmic diagram of the temporal voltage profile in the case of a switching arc ignition,

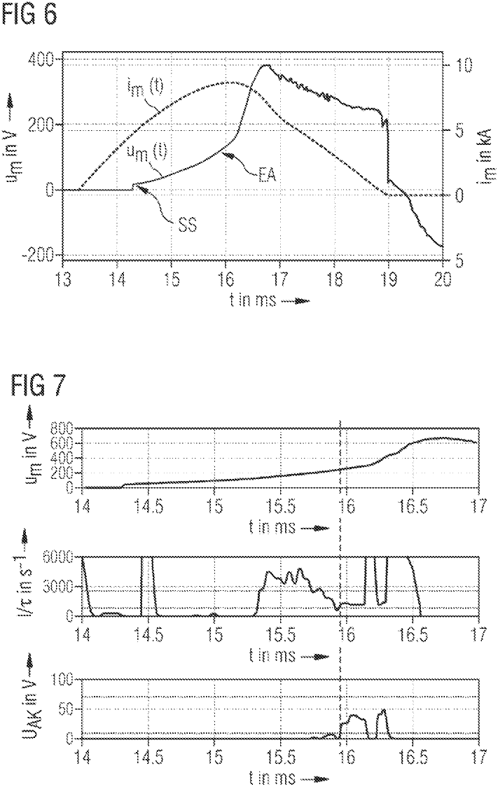

FIG. 6 shows a second diagram of the temporal voltage and current profiles in the case of a switching arc ignition,

FIG. 7 shows a diagram of the temporal profile of variables for switching arc detection,

FIG. 8 shows a block diagram of an arc detection unit according to the invention,

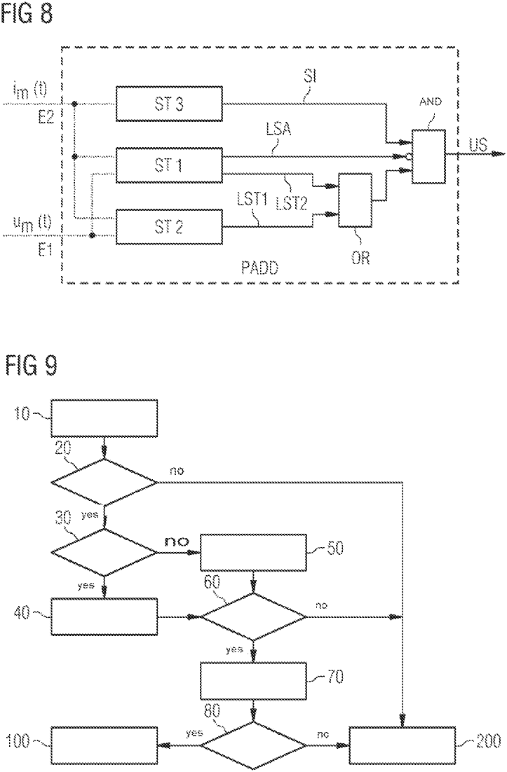

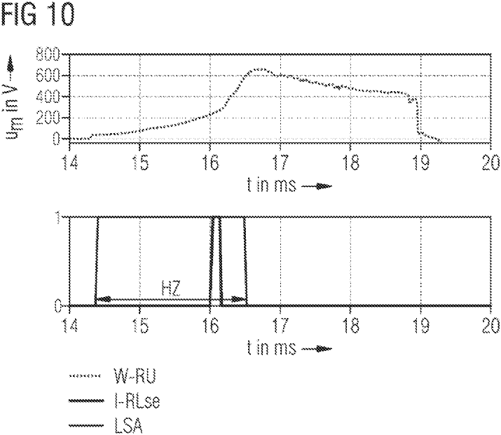

FIG. 9 shows a flow chart for switching arc detection,

FIG. 10 shows a diagram of temporal detection criteria.

FIG. 1 shows an equivalent circuit diagram of an electrical circuit, such as a low-voltage AC circuit, for example, wherein a three-phase AC network would be realized in an analogous manner, comprising an electrical energy source 100, which provides an electrical network voltage u_{N}(t), an infeed cable 200 connected thereto, represented by electrical equivalent circuit elements, such as an infeed cable resistance R_{EK} and an infeed cable inductance or coil L_{EK}, which is followed by an electrical load, operating means or energy sink 300, represented in turn by electrical equivalent circuit elements, such as a load resistance R_{BM} and a load inductance or coil L_{BM}. An electrical voltage uₘ(t) and an electrical current variable, such as the electrical current value iₘ(t) or/and the change in the current with respect to time i’ₘ(t), or respectively the first derivative of the current with respect to time, can be measured between the infeed cable 200 and the load 300.

These variables, in particular the electrical voltage or electrical voltage values, are detected at the measurement points 600 in order to be processed further in an arrangement for arc detection according to the invention.

The region monitored with respect to arcs is represented by a dashed line 500.

An arc can occur in the electrical circuit, said arc being represented symbolically by an arc 400 having an arc voltage U_{LB}(t).

For this circuit, it is possible to formulate an ansatz equation describing the electrical relationships in the circuit:

$${\text{u}}_{\text{m}} \left(\text{t}\right) = {\text{R}}_{\text{BM}} ⋅ {\text{i}}_{\text{m}} \left(\text{t}\right) + {\text{L}}_{\text{BM}} \frac{{\text{di}}_{\text{m}} \left(\text{t}\right)}{\text{dt}}$$

Assuming that an arc is present in the low-voltage network, the electrical behavior would be comparable with that of a back-EMF source in the network.

This results in the following, extended ansatz differential equation:

$${\text{u}}_{\text{m}} \left(\text{t}\right) = {\text{R}}_{\text{BM}} ⋅ {\text{i}}_{\text{m}} \left(\text{t}\right) + {\text{L}}_{\text{BM}} \frac{{\text{di}}_{\text{m}} \left(\text{t}\right)}{\text{dt}} + {\text{u}}_{\text{LB}} \left(\text{t}\right)$$

An arc fault is simulated in a simplified manner as a purely resistive load. It is thus assumed that the arc voltage is in phase with the arc current. The arc voltage can thus be described by the following equation (A – amperes, sign – sign function):

$${\text{u}}_{\text{LB}} \left(\text{t}\right) = {\text{U}}_{\text{LB}} ⋅ \text{sign} \left({\text{i}}_{\text{LB}} \left(\text{t}\right) / A\right)$$

If it is assumed that the measurement current iₘ(t) corresponds to the arc fault current i_{LB}(t), that is to say that no current branching is present between the measurement location and the arc fault burning location, the following can be written:

$${\text{u}}_{\text{m}} \left(\text{t}\right) = {\text{R}}_{\text{BM}} ⋅ {\text{i}}_{\text{m}} \left(\text{t}\right) + {\text{L}}_{\text{BM}} \frac{{\text{di}}_{\text{m}} \left(\text{t}\right)}{\text{dt}} + \text{sign} \left({\text{i}}_{\text{m}} \left(\text{t}\right) / A\right) ⋅ {\text{U}}_{\text{LB}}$$

Various methods can be used to solve this extended ansatz differential equation. In this context, reference is made to the following patent applications:
PCT/EP2016/062274
PCT/EP2016/062273
PCT/EP2016/062272
PCT/EP2016/062271
PCT/EP2017/062980
(European patent office and:
102016209444.0
102016209443.2
102016209445.9
(German patent office)
the content of which is hereby incorporated by reference in this patent application.

They contain solutions for determining an arc fault (but not for determining a switching arc). The circuit diagram and the above approach in accordance with FIG. 1 do not allow a distinction to be drawn between arc faults and switching arcs.

For the dependable detection of arc faults and to differentiate them from switching arcs, it is necessary to detect switching arcs individually.

According to the simplified equivalent circuit diagram in accordance with FIG. 1, depending on the type of arc - arc fault or switching arc, a significant voltage profile arises, which deviates particularly at the time of ignition.

In the circuit or network in which an arc burns, a current and voltage profile having a significant profile can be measured. A typical temporal voltage profile uₘ(t) and temporal current profile iₘ(t) for an arc fault is illustrated in FIG. 2. The latter shows an illustration of a diagram illustrating the temporal profile of the electrical voltage U and of the electrical current I after ignition of an arc or arc fault, in particular parallel arc fault, in an electrical circuit, in particular low-voltage circuit.

Time t in milliseconds (ms) [t in ms] is represented on the horizontal X-axis. The magnitude of the electrical voltage in volts (V) [uₘ in V] is depicted on the vertical y-axis on the left scale. The magnitude of the electrical current iₘ in kiloamperes (kA) [iₘ in kA] is depicted on the right scale.

After arc ignition, the current I continues with an approximately sinusoidal profile. The voltage U has a profile that is severely distorted, approximately “sawtooth-shaped” with rapid voltage changes. Roughly interpreted, to a first approximation, the voltage profile is rectangular, instead of a customarily sinusoidal profile. Considered in the abstract, it is possible to identify in the voltage profile a rectangular waveform exhibiting a highly stochastic component on the plateau. The rectangular waveform is characterized in that during the arc ignition and in the subsequent voltage zero crossings of the AC voltage, significantly increased voltage changes occur, which are referred to hereinafter as voltage jump, since the rise in the voltage change is significantly greater in comparison with a sinusoidal voltage profile.

FIG. 3 shows a diagram of the temporal voltage and current profiles in accordance with FIG. 2, with the difference of switching arc ignition.

If the profiles in accordance with FIGS. 2 and 3 are represented semilogarithmically, then the behavior that is typical of a switching arc and deviates from the arc fault is manifested in the voltage profile according to FIGS. 4 and 5.

FIG. 4 shows an illustration of the temporal voltage profile uₘ(t), uₘ(t)log in the case of arc fault ignition in accordance with FIG. 2 firstly in a linear plot uₘ(t) and secondly in a semilogarithmic plot uₘ(t)log. Time t in milliseconds (ms) [t in ms] is represented on the horizontal Y-axis. The magnitude of the electrical voltage uₘ in volts (V) [uₘ in V] is depicted in a linear representation on the vertical Y-axis on the left scale. The magnitude of the electrical voltage uₘ in volts (V) [uₘ in V] is depicted in a logarithmic representation on the right scale.

FIG. 5 shows a diagram in accordance with FIG. 4, with the difference of switching arc ignition.

It has been discovered according to the invention that in the case of a switching arc, an approximated exponential function is present in the voltage profile at the time of ignition, which exponential function is intended to be used according to the invention for the detection of a switching arc. FIG. 5 shows the approximated profile in the range of approximately 1.2 ms, i.e. between the two vertical lines in the diagram.

According to the invention, this significant voltage profile of a switching arc for this ignition range is described as follows (U_{AK} - anode-cathode voltage between the open contacts, 20...30 V in the case of single-break interrupters and 40...60 V in the case of double-break interrupters; A - amperes):

$${\text{u}}_{\text{LB}} \left(\text{t}\right) = {\text{U}}_{\text{AK}} s g n \left(\frac{{\text{i}}_{\text{m}} \left(\text{t}\right)}{A}\right) {e}^{\left(t - t o\right) / τ}$$

After insertion into the ansatz equations (equation 2), the following can be described for a switching arc, in contrast to an arc fault (equation 4), for the arc ignition range:

$${\text{u}}_{\text{m}} \left(\text{t}\right) = {\text{R}}_{\text{BM}} ⋅ {\text{i}}_{\text{m}} \left(\text{t}\right) + {\text{L}}_{\text{BM}} \frac{{\text{di}}_{\text{m}} \left(\text{t}\right)}{\text{dt}} + {\text{U}}_{\text{AK}} s g n \left(\frac{{\text{i}}_{\text{m}} \left(\text{t}\right)}{A}\right) {e}^{\left(t - t o\right) / τ}$$

The expression (t-to)/τ is the exponent of the exponential function. According to the invention, the voltage profile of a switching arc is described by an abstract exponential function, as illustrated in FIG. 5.

That is to say if the exponent (t-to)τ of the exponential function lies within a first range, a switching arc is present. That is to say that a switching arc detection signal can be output by an arrangement in this case. The arrangement determines exponents of the exponential function continuously from (continuously/periodically) determined voltage and current values.

As a further or additional, significant criterion, in the voltage profile of a switching arc, it is possible to identify a voltage jump at the time of contact opening. FIG. 6 shows this voltage jump SS.

FIG. 6 shows a diagram in accordance with FIG. 3, with the difference that the voltage jump SS and the exponential rise EA are marked.

According to the switch typology used, this voltage jump differs depending on the number of contacts connected in series. The profile in FIG. 6 shows a voltage jump of a single-break interrupter contact. Two voltage jumps should be assumed in the case of a double-break interrupter contact.

The voltage jump occurs directly after the time of contact opening and describes the ignition of the arc and results – when derived physically – from the anode-cathode voltage drop U_{AK} of the arc. According to the approximated exponential function, the voltage jump can be described by the scaling factor of the exponential function.

The scaling factor and thus also the voltage jump can be determined by means of different algorithms. For example by means of a calculation using the so-called W-RU algorithm or the W-Rus algorithm, which were developed on the basis of a wavelet transformation, in order to determine an equivalent voltage jump in the signal profile.

A determination using the W-RU algorithm is described for example in the German patent application having the application number 10 2016 209 445.9. A determination using the W-Rus algorithm is described for example in the European patent application having the application number PCT/EP2016/062271 (EP) (both cited above and incorporated by reference).

An alternative to determining the voltage jump would be the (continuous or periodic) determination of the change in the voltage with respect to time. If the change in the voltage with respect to time or the first derivative of the voltage with respect to time exceeds a first jump limit value, the value of which can be between 10 and 30 volts, in particular from 12 to 25 volts (as a typical anode-cathode voltage drop), a voltage jump of a switching arc is present, particularly if it is followed by an exponential function.

A method for determining an exponential function and whether the determined exponent of the exponential function lies within the first range is possible by means of a numerical calculation on the basis of an extended, modified distance protection algorithm. The following differentiating and integrating algorithms are respectively suitable for this according to the desired accuracy and the model network present:

| Algorithm | | Calculated variables | | | | | Ansatz equation |
|---|---|---|---|---|---|---|---|
| | | R_{BM} | L_{BM} | U_{AK} | τ | | |
| Differentiating | D-se | | | × | × | $u \left(t\right) = {U}_{A K} s g n \left(\frac{i \left(t\right)}{A}\right) e \frac{t - {t}_{0}}{τ}$ | |
| | D-Rse | × | | × | × | $u \left(t\right) = {R}_{B M} i \left(t\right) + {U}_{A K} s g n \left(\frac{i \left(t\right)}{A}\right) e \frac{t - {t}_{0}}{τ}$ | |
| | D-Lse | | × | × | × | $u \left(t\right) = {L}_{B M} \frac{d i \left(t\right)}{d t} + {U}_{A K} s g n \left(\frac{i \left(t\right)}{A}\right) e \frac{t - {t}_{0}}{τ}$ | |
| | D-RLse | × | × | × | × | $u \left(t\right) = {R}_{B M} i \left(t\right) + {L}_{B M} \frac{d i \left(t\right)}{d t} + {U}_{A K} s g n \left(\frac{i \left(t\right)}{A}\right) e \frac{t - {t}_{0}}{τ}$ | |
| Integrating | I-se | | | × | × | $\int u \left(t\right) d t = {U}_{A K} \int s g n \left(\frac{i \left(t\right)}{A}\right) e \frac{t - {t}_{0}}{τ} d t$ | |
| | I-Rse | × | | × | × | $\int u \left(t\right) d t = {R}_{B M} \int i \left(t\right) d t + {U}_{A K} \int s g n \left(\frac{i \left(t\right)}{A}\right) e \frac{t - {t}_{0}}{τ} d t$ | |
| | I-Lse | | × | × | × | $\int u \left(t\right) d t = {L}_{B M} \int \frac{d i \left(t\right)}{d t} d t + {U}_{A K} \int s g n \left(\frac{i \left(t\right)}{A}\right) e \frac{t - {t}_{0}}{τ} d t$ | |
| | I-RLse | × | × | × | × | $\int u \left(t\right) d t = {R}_{B M} \int i \left(t\right) d t + {L}_{B M} \int \frac{d i \left(t\right)}{d t} + {U}_{A K} \int s g n \left(\frac{i \left(t\right)}{A}\right) e \frac{t - {t}_{0}}{τ} d t$ | |

The findings from the development of numerical detection algorithms for detecting arc faults (see the patent applications referenced) show that good results are attainable when calculating the unknown parameters of the ansatz equation in the case of a complete integrating solution approach.

The novel method according to the invention or the novel algorithm according to the invention was developed for distinguishing between switching arcs and arc faults. The (integrating) I-RLse algorithm is particularly well suited to this. This algorithm is based on the I-RLs algorithm developed for the arc faults and constitutes an approach modified according to the invention. In future, using the I-RLse algorithm, it will be possible to detect both an arc fault and a switching arc.

Besides the parameters RBM, LBM, U_{AK} and τ it is additionally helpful to determine the point in time t0. The point in time t0 defines the point in time at which the voltage jump in the form of the anode-cathode voltage drop occurs. Since the latter can be detected in the form of a signal profile algorithm, for example, or if the change in the voltage with respect to time exceeds the first jump limit value, the point in time t0 can be determined by way of this, of example.

By solving equation 6, it is possible to determine the parameters – to be evaluated for the switching arc detection – of voltage jump SS or U_{AK}, or/and the exponent of the exponential function or τ. If both calculated parameters simultaneously lie within defined limit ranges, a switching arc is deemed to have been detected.

This is illustrated by way of example in FIG. 7. FIG. 7 shows a diagram of the temporal profile of variables for switching arc detection. The top diagram of FIG. 7 illustrates the temporal voltage profile uₘ(t) of the switching arc ignition in accordance with FIG. 3 or FIG. 6.

The middle diagram illustrates the determined exponent of the exponential function, represented by the value ⅟τ in s⁻¹ in the example. The value range of ⅟τ in s⁻¹, in the example 0...3000...6000 s⁻¹, is plotted on the vertical Y-axis. Two horizontal lines for the limit values 800 s⁻¹ and 2700 s⁻¹ are plotted parallel to the horizontal X-axis. The first range would be from 800 s⁻¹ to 2700 s⁻¹ in this example.

In the bottom diagram, the voltage jump U_{AK} (= UAK) is plotted against time. The magnitude of the electrical voltage U_{AK} in volts (V) [U_{AK} in V] is depicted on the vertical axis. A horizontal line for the limit value U_{AK} of 9.5 V is shown parallel to the horizontal axis. That is to say that if a voltage jump of greater than 9.5 V is present (or an equivalent jump limit value of the change in the voltage with respect to time), at least one criterion for a switching arc is present. Time t in milliseconds (ms) [t in ms] is represented on the horizontal X-axis for all three diagrams.

A vertically dashed line is shown at the point in time just before 16 ms. Two positive criteria of the switching arc detection are present at this point in time. Firstly, the exponent of the exponential function lies within the first range. Secondly, a voltage jump of greater than 9.5 V is present. Consequently, at this point in time a switching arc is detected and a switching arc detection signal can be output. The detection of the voltage jump can be limited at the upper end, as is depicted by a further horizontal line at 70 volts (upper limitation) in the bottom diagram in FIG. 7. That is to say that a voltage jump of greater than 70 volts would not be taken into account in this case.

According to the invention, the switching arc detection can be combined with a predictive overcurrent release. That is to say that a switching arc detection signal is output only if the current, i.e. a first number of current values for example, exceeds a first current limit value.

FIG. 8 shows a possible combination of the switching arc detection according to the invention with an arc fault detection in an arrangement PADD. The arrangement PADD comprises a first input E1 for the electrical voltage uₘ(t) and a second input E2 for an electrical current variable, such as the electrical current value iₘ(t) or/and the change in the current with respect to time i’ₘ(t), in the example iₘ(t). The electrical voltage uₘ(t) and the electrical current variable are fed to a first control unit ST1, which determines the presence of a switching arc. A switching arc detection signal LSA is output in the case of a positive switching arc determination. The first control unit ST1 can carry out the switching arc determination for example by means of an extended distance protection algorithm, e.g. I-RLse algorithm. The first control unit ST1 can furthermore be configured in such a way that it carries out an arc fault determination. For example using the same or a different algorithm (see the patent applications referenced).

Alternatively or additionally, the arc fault determination can also be carried out by means of a second control unit ST2. For this purpose, the electrical voltage uₘ(t) and the electrical current variable are fed to the second control unit ST2. The second control unit S2 outputs a first arc fault detection signal LST1 in the case where an arc fault is detected.

In the example in accordance with FIG. 8, the arrangement PADD comprises a first and a second control unit ST1, ST2, the first control unit ST1 carrying out both a switching arc determination and an arc fault determination. For this purpose, it outputs the switching arc detection signal LSA and a second arc fault detection signal LST2, respectively.

The arrangement in accordance with FIG. 8 can comprise, as illustrated, a third control unit ST3, for example with a predictive overcurrent release. That is to say that the electrical current variable, such as the electrical current value iₘ(t) or/and the change in the current with respect to time i’ₘ(t), is fed to the third control unit ST3. A current release signal SI is output in the case where the first current limit value is exceeded. The current release signal SI can be output only if a first number of current values are exceeded, i.e. the current is present for a first time period.

The control units in accordance with FIG. 8 can be linked in such a way that the arc fault detection signal(s), in the example LST1 and LST2, are ORed with one another, for example by an OR unit OR.

The ORed arc fault detection signal(s) can be ANDed with the switching arc detection signal, for example by an AND unit AND, the AND unit having an inverted input for the switching arc detection signal LSA, such that in the case where a switching arc detection signal LSA is present, the AND unit does not output a positive signal. The AND unit AND can output an interruption signal US, for example for an interruption of the electrical circuit, for example by a low-voltage circuit breaker. An interruption signal US is output only if an arc fault has been detected, i.e. a first or/and second arc fault detection signal LST1, LST2 is/are present, and no switching arc has been detected, i.e. no (positive) switching arc detection signal LSA is present.

Furthermore, the current release signal SI of the third control unit ST3 can likewise be fed to the AND unit AND, as illustrated in FIG. 8, such that an interruption signal US is output only if a current release signal SI is present.

The second control unit ST2 can furthermore be configured in such a way that a determination of the point in time t0 is carried out, i.e. if e.g. the first jump limit value is exceeded or a voltage jump exceeding a voltage jump magnitude is present. The determination of the point in time t0 can be reported to the first control unit ST1, which is indicated by an arrow between the first and second control units. The first control unit can thus apply the presence of the switching arc criterion or/and start a determination of the exponential function or the exponent thereof.

The second control unit ST2 can carry out e.g. a signal profile analysis (see the patent applications referenced).

FIG. 9 shows a possible method sequence that can be realized e.g. in the form of a further algorithm.

A step 10 involves continuously calculating the exponent of the exponential function, for example τ⁻¹, and continuously detecting a voltage jump or the exceedance of the first jump limit value.

In a step 20, in the case where a jump is detected, a check is made to ascertain whether the point in time t0 has already been set, step 30. If the outcome of the check is no, step 50, the point in time t0 is set to the present point in time. If the outcome of the check is yes, step 40, the set point in time t0 is used. Step 60 involves carrying out the check to establish whether the exponent of the exponential function lies within the first range. If the outcome of the check is no, the method sequence jumps to step 200, i.e. that no switching arc is present, and the method sequence starts afresh. If the outcome of the check is yes, the method sequence jumps to step 70 and e.g. the magnitude of the voltage jump U_{AK} is determined. If U_{AK} is greater than a threshold value or within a further range, a switching arc is detected in step 100, otherwise with step 200 no switching arc is present. In both cases the algorithm can start afresh.

If no jump is detected in step 20, with step 200 no switching arc is present.

FIG. 10 illustrates the interaction of temporal detection criteria in two diagrams. The upper diagram shows the voltage profile of a switching arc in accordance with FIGS. 3 or 6. The lower diagram shows the detection behavior of two algorithms, firstly of the W-RU algorithm (large window with hold time HZ) and secondly of the I-RLse algorithm (narrow window), which directly in interaction with the W-RU algorithm leads to the outputting of a switching arc detection signal LSA.

The signal profile algorithm (W-RU) detects the voltage jump and thus already provides a base point release for the I-RLse algorithm according to FIG. 10.

The solution to the ansatz equation for the circuit by way of an integrating method which, on account of four unknowns, likewise requires four different integration limits is merely one example of the solution possibilities. A further possibility would be, for example, solution using MKQ algorithms based on the least squares method.

The detection algorithm according to the invention for detecting switching arcs can firstly be used for distinguishing between switching arcs and arc faults during arc fault detection using numerical detection algorithms. The algorithm can secondly also be used as an additional function in the case of existing arc fault protection systems that operate e.g. on the basis of optical detection, since systems of this type often have problems if a switching arc of high current intensity occurs in the region to be protected and monitored.

Moreover, it is possible to use the algorithm in combination with numerical methods of arc fault detection, in order for example rapidly to detect a circuit breaker failure of a downstream circuit breaker and to clarify the fault correspondingly rapidly, without delaying corresponding set grading times.

A description is given below of the derivation of the extended distance protection methods or algorithms for detecting switching arcs and thus for delimitation from arc faults. The method or the algorithm is based on the following ansatz equation:

$${u}_{\text{mess}} = {R}_{\text{BM}} {i}_{\text{mess}} + {L}_{\text{BM}} {{i}^{′}}_{\text{mess}} + {U}_{\text{LB}} {e}^{\text{τ} \left(\text{t}\right)} \text{sign} \left(\frac{{i}_{\text{mess}}}{A}\right)$$

I-RLse calculation/algorithm (with numbering beginning anew):

$${u}_{1} = {R}_{\text{BM}} {i}_{1} + {L}_{\text{BM}} {{i}^{′}}_{\text{1}} + {U}_{\text{LB}} {e}^{\text{τ} \left(t\right)} {s}_{1}$$

$${u}_{2} = {R}_{\text{BM}} {i}_{2} + {L}_{\text{BM}} {{i}^{′}}_{2} + {U}_{\text{LB}} {e}^{\text{τ} \left(t + 1 \text{Δ} T\right)} {s}_{2}$$

$${u}_{3} = {R}_{\text{BM}} {i}_{3} + {L}_{\text{BM}} {{i}^{′}}_{3} + {U}_{\text{LB}} {e}^{\text{τ} \left(t + 2 \text{Δ} T\right)} {s}_{3}$$

$${u}_{4} = {R}_{\text{BM}} {i}_{4} + {L}_{\text{BM}} {{i}^{′}}_{4} + {U}_{\text{LB}} {e}^{\text{τ} \left(t + 3 \text{Δ} T\right)} {s}_{4}$$

Rearranging with respect to R

$$\frac{{u}_{1} - {L}_{\text{BM}} {{i}^{′}}_{1} - {U}_{\text{LB}} {e}^{\text{τ} \left(t\right)} {s}_{1}}{{i}_{1}} = {R}_{\text{BM}}$$

$$\frac{{u}_{2} - {L}_{\text{BM}} {{i}^{′}}_{2} - {U}_{\text{LB}} {e}^{\text{τ} \left(t + 1 \text{Δ} T\right)} {s}_{2}}{{i}_{2}} = {R}_{\text{BM}}$$

$$\frac{{u}_{3} - {L}_{\text{BM}} {{i}^{′}}_{3} - {U}_{\text{LB}} {e}^{\text{τ} \left(t + 2 \text{Δ} T\right)} {s}_{3}}{{i}_{3}} = {R}_{\text{BM}}$$

$$\frac{{u}_{4} - {L}_{\text{BM}} {{i}^{′}}_{4} - {U}_{\text{LB}} {e}^{\text{τ} \left(t + 3 \text{Δ} T\right)} {s}_{4}}{{i}_{4}} = {R}_{\text{BM}}$$

Equating the 1^{st} and 2^{nd} and 3^{rd} and 4^{th} formulae and solving for L

$$\frac{{u}_{1} - {L}_{\text{BM}} {{i}^{′}}_{1} - {U}_{\text{LB}} {e}^{\text{τ} \left(t\right)} {s}_{1}}{{i}_{1}} = \frac{{u}_{2} - {L}_{\text{BM}} {{i}^{′}}_{2} - {U}_{\text{LB}} {e}^{\text{τ} \left(t + 1 \text{Δ} T\right)} {s}_{2}}{{i}_{2}}$$

$$\frac{{u}_{3} - {L}_{\text{BM}} {{i}^{′}}_{3} - {U}_{\text{LB}} {e}^{\text{τ} \left(t + 2 \text{Δ} T\right)} {s}_{3}}{{i}_{3}} = \frac{{u}_{4} - {L}_{\text{BM}} {{i}^{′}}_{4} - {U}_{\text{LB}} {e}^{\text{τ} \left(t + 3 \text{Δ} T\right)} {s}_{4}}{{i}_{4}}$$

Rearranging

$${u}_{1} {i}_{2} - {L}_{\text{BM}} {{i}^{′}}_{1} {i}_{2} - {U}_{\text{LB}} {e}^{\text{τ} \left(t\right)} {s}_{1} {i}_{2} = {u}_{2} {i}_{1} - {L}_{\text{BM}} {{i}^{′}}_{2} {i}_{1} - {U}_{\text{LB}} {e}^{\text{τ} \left(t + 1 \text{Δ} T\right)} {s}_{2} {i}_{1}$$

$${u}_{3} {i}_{4} - {L}_{\text{BM}} {{i}^{′}}_{3} {i}_{4} - {U}_{\text{LB}} {e}^{\text{τ} \left(t + 2 \text{Δ} T\right)} {s}_{3} {i}_{4} = {u}_{4} {i}_{3} - {L}_{\text{BM}} {{i}^{′}}_{4} {i}_{3} - {U}_{\text{LB}} {e}^{\text{τ} \left(t + 3 \text{Δ} T\right)} {s}_{4} {i}_{3}$$

Simplifying

$${L}_{\text{BM}} \text{=} \frac{{u}_{2} {i}_{1} - {U}_{\text{LB}} {e}^{\text{τ} \left(t + 1 \text{Δ} T\right)} {s}_{2} {i}_{1} + {U}_{\text{LB}} {e}^{\text{τ} \left(t\right)} {s}_{1} {i}_{2} - {u}_{1} {i}_{2}}{{{i}^{′}}_{2} {i}_{1} - {{i}^{′}}_{1} {i}_{2}}$$

$${L}_{\text{BM}} \text{=} \frac{{u}_{4} {i}_{3} - {U}_{\text{LB}} {e}^{\text{τ} \left(t + 3 \text{Δ} T\right)} {s}_{4} {i}_{3} + {U}_{\text{LB}} {e}^{\text{τ} \left(t + 2 \text{Δ} T\right)} {s}_{3} {i}_{4} - {u}_{3} {i}_{4}}{{{i}^{′}}_{4} {i}_{3} - {{i}^{′}}_{3} {i}_{4}}$$

Equating

$$\begin{matrix}\frac{{u}_{2} {i}_{1} - {U}_{\text{LB}} {e}^{\text{τ} \left(t + 1 \text{Δ} T\right)} {s}_{2} {i}_{1} + {U}_{\text{LB}} {e}^{\text{τ} \left(t\right)} {s}_{1} {i}_{2} - {u}_{1} {i}_{2}}{{{i}^{′}}_{2} {i}_{1} - {{i}^{′}}_{1} {i}_{2}} \\ = \frac{{u}_{4} {i}_{3} - {U}_{\text{LB}} {e}^{\text{τ} \left(t + 3 \text{Δ} T\right)} {s}_{4} {i}_{3} + {U}_{\text{LB}} {e}^{\text{τ} \left(t + 2 \text{Δ} T\right)} {s}_{3} {i}_{4} - {u}_{3} {i}_{4}}{{{i}^{′}}_{4} {i}_{3} - {{i}^{′}}_{3} {i}_{4}}\end{matrix}$$

Rearranging for U-LB

$$\begin{matrix}\frac{{u}_{2} {i}_{1} - {u}_{1} {i}_{2}}{{{i}^{′}}_{2} {i}_{1} - {{i}^{′}}_{1} {i}_{2}} + \frac{{U}_{\text{LB}} {e}^{\text{τ} \left(t\right)} {s}_{1} {i}_{2} - {U}_{\text{LB}} {e}^{\text{τ} \left(t + 1 \text{Δ} T\right)} {s}_{2} {i}_{1}}{{{i}^{′}}_{2} {i}_{1} - {{i}^{′}}_{1} {i}_{2}} = \\ \frac{{u}_{4} {i}_{3} - {u}_{3} {i}_{4}}{{{i}^{′}}_{4} {i}_{3} - {{i}^{′}}_{3} {i}_{4}} + \frac{{U}_{\text{LB}} {e}^{\text{τ} \left(t + 2 \text{Δ} T\right)} {s}_{3} {i}_{4} - {U}_{\text{LB}} {e}^{\text{τ} \left(t + 3 \text{Δ} T\right)} {s}_{4} {i}_{3}}{{{i}^{′}}_{4} {i}_{3} - {{i}^{′}}_{3} {i}_{4}}\end{matrix}$$

Simplifying

$${U}_{\text{LB}} = \frac{\frac{{u}_{4} {i}_{3} - {u}_{3} {i}_{4}}{{{i}^{′}}_{4} {i}_{3} - {{i}^{′}}_{3} {i}_{4}} - \frac{{u}_{2} {i}_{1} - {u}_{1} {i}_{2}}{\left({{i}^{′}}_{2} {i}_{1} - {{i}^{′}}_{1} {i}_{2}\right)}}{\frac{{e}^{\text{τ} \left(t\right)} {s}_{1} {i}_{2} - {e}^{\text{τ} \left(t + 1 \text{Δ} T\right)} {s}_{2} {i}_{1}}{{{i}^{′}}_{2} {i}_{1} - {{i}^{′}}_{1} {i}_{2}} - \frac{{e}^{\text{τ} \left(t + 2 \text{Δ} T\right)} {s}_{3} {i}_{4} - {e}^{\text{τ} \left(t + 3 \text{Δ} T\right)} {s}_{4} {i}_{3}}{{{i}^{′}}_{4} {i}_{3} - {{i}^{′}}_{3} {i}_{4}}}$$

$$\begin{matrix}{U}_{\text{LB}} = \\ \frac{\frac{\left({{i}^{′}}_{2} {i}_{1} - {{i}^{′}}_{1} {i}_{2}\right) \left({u}_{4} {i}_{3} - {u}_{3} {i}_{4}\right) - \left({{i}^{′}}_{4} {i}_{3} - {{i}^{′}}_{3} {i}_{4}\right) \left({u}_{2} {i}_{1} - {u}_{1} {i}_{2}\right)}{\left({{i}^{′}}_{4} {i}_{3} - {{i}^{′}}_{3} {i}_{4}\right) ∗ \left({{i}^{′}}_{2} {i}_{1} - {{i}^{′}}_{1} {i}_{2}\right)}}{\frac{\left({e}^{\text{τ} \left(t\right)} {s}_{1} {i}_{2} - {e}^{\text{τ} \left(t + 1 \text{Δ} T\right)} {s}_{2} {i}_{1}\right) \left({{i}^{′}}_{4} {i}_{3} - {{i}^{′}}_{3} {i}_{4}\right) - \left({{i}^{′}}_{2} {i}_{1} - {{i}^{′}}_{1} {i}_{2}\right) \left({e}^{\text{τ} \left(t + 2 \text{Δ} T\right)} {s}_{3} {i}_{4} - {e}^{\text{τ} \left(t + 3 \text{Δ} T\right)} {s}_{4} {i}_{3}\right)}{\left({{i}^{′}}_{4} {i}_{3} - {{i}^{′}}_{3} {i}_{4}\right) ∗ \left({{i}^{′}}_{2} {i}_{1} - {{i}^{′}}_{1} {i}_{2}\right)}}\end{matrix}$$

$$\begin{matrix}{U}_{\text{LB}} = \\ \frac{\left({{i}^{′}}_{2} {i}_{1} - {{i}^{′}}_{1} {i}_{2}\right) \left({u}_{4} {i}_{3} - {u}_{3} {i}_{4}\right) - \left({{i}^{′}}_{4} {i}_{3} - {{i}^{′}}_{3} {i}_{4}\right) \left({u}_{2} {i}_{1} - {u}_{1} {i}_{2}\right)}{\left({{i}^{′}}_{4} {i}_{3} - {{i}^{′}}_{3} {i}_{4}\right) \left({e}^{\text{τ} \left(t\right)} {s}_{1} {i}_{2} - {e}^{\text{τ} \left(t + 1 \text{Δ} T\right)} {s}_{2} {i}_{1}\right) - \left({{i}^{′}}_{2} {i}_{1} - {{i}^{′}}_{1} {i}_{2}\right) \left({e}^{\text{τ} \left(t + 2 \text{Δ} T\right)} {s}_{3} {i}_{4} - {e}^{\text{τ} \left(t + 3 \text{Δ} T\right)} s\right)}\end{matrix}$$

$$\begin{matrix}{U}_{\text{LB}} = \frac{a}{b} = \\ \frac{\left({{i}^{′}}_{2} {i}_{1} - {{i}^{′}}_{1} {i}_{2}\right) \left({u}_{4} {i}_{3} - {u}_{3} {i}_{4}\right) - \left({{i}^{′}}_{4} {i}_{3} - {{i}^{′}}_{3} {i}_{4}\right) \left({u}_{2} {i}_{1} - {u}_{1} {i}_{2}\right)}{\left({{i}^{′}}_{4} {i}_{3} - {{i}^{′}}_{3} {i}_{4}\right) \left({e}^{\text{τ} \left(t\right)} {s}_{1} {i}_{2} - {e}^{\text{τ} \left(t + 1 \text{Δ} T\right)} {s}_{2} {i}_{1}\right) - \left({{i}^{′}}_{2} {i}_{1} - {{i}^{′}}_{1} {i}_{2}\right) \left({e}^{\text{τ} \left(t + 2 \text{Δ} T\right)} {s}_{3} {i}_{4} - {e}^{\text{τ} \left(t + 3 \text{Δ} T\right)} s\right)}\end{matrix}$$

Calculating b

$$\begin{matrix}b = \left({i}^{′} {\text{}}_{4} {i}_{3} - {i}^{′} {\text{}}_{3} {i}_{4}\right) \left({e}^{τ \left(t\right)} {s}_{1} {i}_{2} - {e}^{\text{τ} \left(t + 1 Δ T\right)} {s}_{2} {i}_{1}\right) - \left({i}^{′} {\text{}}_{2} {i}_{1} - {i}^{′} {\text{}}_{1} {i}_{2}\right) \\ \left({e}^{\text{τ} \left(t + 2 Δ T\right)} {s}_{3} {i}_{4} - {e}^{\text{τ} \left(t + 3 Δ T\right)} {s}_{4} {i}_{3}\right)\end{matrix}$$

$$\begin{matrix}b = {e}^{\text{τ} \left(t\right)} \left({s}_{1} {i}_{2} {i}^{′} {\text{}}_{4} {i}_{3} - {s}_{1} {i}_{2} {i}^{′} {\text{}}_{3} {i}_{4}\right) - {e}^{\text{τ} \left(t + 1 Δ T\right)} \left({s}_{2} {i}_{1} {i}^{′} {\text{}}_{4} {i}_{3} -\right) \\ \left({s}_{2} {i}_{1} {i}^{′} {\text{}}_{3} {i}_{4}\right) - {e}^{\text{τ} \left(t + 2 Δ T\right)} \left({s}_{3} {i}_{4} {i}^{′} {\text{}}_{2} {i}_{1} - {s}_{3} {i}_{4} {i}^{′} {\text{}}_{1} {i}_{2}\right) + {e}^{\text{τ} \left(t + 3 Δ T\right)} \\ \left({s}_{4} {i}_{3} {i}^{′} {\text{}}_{2} {i}_{1} - {s}_{4} {i}_{3} {i}^{′} {\text{}}_{1} {i}_{2}\right)\end{matrix}$$

Substitution for e^{τΔT}= x

$$\begin{matrix}b = {e}^{\text{τ} \left(t\right)} \\ \left({s}_{4} {i}_{3} \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right) {x}^{2} - {s}_{2} {i}_{1} \left({i}^{′} {\text{}}_{4} {i}_{3} - {i}^{′} {\text{}}_{3} {i}_{4}\right) x +\right) \\ {s}_{1} {i}_{2} \left({i}^{′} {\text{}}_{4} {i}_{3} -\right) \left(\left({i}^{′} {\text{}}_{3} {i}_{4}\right)\right)\end{matrix}$$

Equating the 1^{st} and 3^{rd} and 2^{nd} and 4^{th} formulae and solving for U-LB

$$\frac{{u}_{1} - {L}_{\text{BM}} {i}^{′} {\text{}}_{1} - {U}_{\text{LB}} {e}^{\text{τ} \left(t\right)} {s}_{1}}{{i}_{1}} = \frac{{u}_{3} - {L}_{\text{BM}} {i}^{′} {\text{}}_{3} - {U}_{\text{LB}} {e}^{\text{τ} \left(t + 2 Δ T\right)} {s}_{3}}{{i}_{3}}$$

$$\frac{{u}_{2} - {L}_{\text{BM}} {i}^{′} {\text{}}_{2} - {U}_{\text{LB}} {e}^{\text{τ} \left(t + 1 Δ T\right)} {s}_{2}}{{i}_{2}} = \frac{{u}_{4} - {L}_{\text{BM}} {i}^{′} {\text{}}_{4} - {U}_{\text{LB}} {e}^{\text{τ} \left(t + 3 Δ T\right)} {s}_{4}}{{i}_{4}}$$

Rearranging for L-BM

$${u}_{1} {i}_{3} - {L}_{\text{BM}} {i}^{′} {\text{}}_{1} {i}_{3} - {U}_{\text{LB}} {e}^{\text{τ} \left(t\right)} {s}_{1} {i}_{3} = {u}_{3} {i}_{1} - {L}_{\text{BM}} {i}^{′} {\text{}}_{3} {i}_{1} - {U}_{\text{LB}} {e}^{\text{τ} \left(t + 2 Δ T\right)} {s}_{3} {i}_{1}$$

$$\begin{matrix}{u}_{2} {i}_{4} - {L}_{\text{BM}} {i}^{′} {\text{}}_{2} {i}_{4} - {U}_{\text{LB}} {e}^{\text{τ} \left(t + 1 Δ T\right)} {s}_{2} {i}_{4} = \\ {u}_{4} {i}_{2} - {L}_{\text{BM}} {i}^{′} {\text{}}_{4} {i}_{2} - {U}_{\text{LB}} {e}^{\text{τ} \left(t + 3 Δ T\right)} {s}_{4} {i}_{2}\end{matrix}$$

$${L}_{\text{BM}} {i}^{′} {\text{}}_{3} {i}_{1} - {L}_{\text{BM}} {i}^{′} {\text{}}_{1} {i}_{3} = {u}_{3} {i}_{1} - {U}_{\text{LB}} {e}^{\text{τ} \left(t + 2 Δ T\right)} {s}_{3} {i}_{1} - {u}_{1} {i}_{3} + {U}_{\text{LB}} {e}^{\text{τ} \left(t\right)} {s}_{1} {i}_{3}$$

$$\begin{matrix}{L}_{\text{BM}} {i}^{′} {\text{}}_{4} {i}_{2} - {L}_{\text{BM}} {i}^{′} {\text{}}_{2} {i}_{4} = \\ {u}_{4} {i}_{2} - {U}_{\text{LB}} {e}^{\text{τ} \left(t + 3 Δ T\right)} {s}_{4} {i}_{2} - {u}_{2} {i}_{4} + {U}_{\text{LB}} {e}^{\text{τ} \left(t + 1 Δ T\right)} {s}_{2} {i}_{4}\end{matrix}$$

$${L}_{\text{BM}} = \frac{{u}_{3} {i}_{1} - {U}_{\text{LB}} {e}^{\text{τ} \left(t + 2 Δ T\right)} {s}_{3} {i}_{1} - {u}_{1} {i}_{3} + {U}_{\text{LB}} {e}^{\text{τ} \left(t\right)} {s}_{1} {i}_{3}}{{i}^{′} {\text{}}_{3} {i}_{1} - {i}^{′} {\text{}}_{1} {i}_{3}}$$

$${L}_{\text{BM}} = \frac{{u}_{4} {i}_{2} - {U}_{\text{LB}} {e}^{\text{τ} \left(t + 3 Δ T\right)} {s}_{4} {i}_{2} - {u}_{2} {i}_{4} + {U}_{\text{LB}} {e}^{\text{τ} \left(t + 1 Δ T\right)} {s}_{2} {i}_{4}}{{i}^{′} {\text{}}_{4} {i}_{2} - {i}^{′} {\text{}}_{2} {i}_{4}}$$

Equating for L-BM

$$\begin{matrix}\frac{{U}_{\text{LB}} {e}^{\text{τ} \left(t\right)} {s}_{1} {i}_{3} - {U}_{\text{LB}} {e}^{\text{τ} \left(t + 2 Δ T\right)} {s}_{3} {i}_{1}}{{i}^{′} {\text{}}_{3} {i}_{1} - {i}^{′} {\text{}}_{2} {i}_{3}} + \frac{{u}_{3} {i}_{1} - {u}_{1} {i}_{3}}{{i}^{′} {\text{}}_{3} {i}_{1} - {i}^{′} {\text{}}_{2} {i}_{3}} \\ = \frac{{U}_{\text{LB}} {e}^{\text{τ} \left(t + 1 Δ T\right)} {s}_{2} {i}_{4} - {U}_{\text{LB}} {e}^{\text{τ} \left(t + 3 Δ T\right)} {s}_{4} {i}_{2}}{{i}^{′} {\text{}}_{4} {i}_{2} - {i}^{′} {\text{}}_{2} {i}_{4}} + \frac{{u}_{4} {i}_{2} - {u}_{2} {i}_{4}}{{i}^{′} {\text{}}_{4} {i}_{2} - {i}^{′} {\text{}}_{2} {i}_{4}}\end{matrix}$$

$$\begin{matrix}{U}_{L B} = \frac{\text{c}}{\text{d}} \\ = \frac{\left({u}_{4} {i}_{2} - {u}_{2} {i}_{4}\right) \left({i}^{′} {\text{}}_{3} {i}_{1} - {i}^{′} {\text{}}_{1} {i}_{3}\right) - \left({u}_{3} {i}_{1} - {u}_{1} {i}_{3}\right) \left({i}^{′} {\text{}}_{4} {i}_{2} - {i}^{′} {\text{}}_{2} {i}_{4}\right)}{\left({e}^{\text{τ} \left(t\right)} {s}_{1} {i}_{3} = {e}^{\text{τ} \left(t + 2 Δ T\right)} {s}_{3} {i}_{1}\right) \left({i}^{′} {\text{}}_{4} {i}_{2} - {i}^{′} {\text{}}_{2} {i}_{4}\right) - \left({e}^{\text{τ} \left(t + 1 Δ T\right)} {s}_{2} {i}_{4} - {e}^{\text{τ} \left(t + 3 Δ T\right)} {s}_{4} {i}_{2}\right) \left({i}^{′} {\text{}}_{3} {i}_{1} - i\right)}\end{matrix}$$

$$\begin{matrix}\text{d} \text{=} \left({e}^{\text{τ} \left(t\right)} {s}_{1} {i}_{3} - {e}^{\text{τ} \left(t + 2 Δ T\right)} {s}_{3} {i}_{1}\right) \left({i}^{′} {\text{}}_{4} {i}_{2} - {i}^{′} {\text{}}_{2} {i}_{4}\right) - \\ \left({e}^{\text{τ} \left(t + 1 Δ T\right)} {s}_{2} {i}_{4} - {e}^{\text{τ} \left(t + 3 Δ T\right)} {s}_{4} {i}_{2}\right) \left({i}^{′} {\text{}}_{3} {i}_{1}\right) \left(- {i}^{′} {\text{}}_{1} {i}_{3}\right)\end{matrix}$$

$$\begin{matrix}\text{d} \text{=} \left({e}^{\text{τ} \left(t\right)} {s}_{1} {i}_{3} - {e}^{\text{τ} \left(t + 2 Δ T\right)} {s}_{3} {i}_{1}\right) \left({i}^{′} {\text{}}_{4} {i}_{2} - {i}^{′} {\text{}}_{2} {i}_{4}\right) - \\ \left({e}^{\text{τ} \left(t + 1 Δ T\right)} {s}_{2} {i}_{4} - {e}^{\text{τ} \left(t + 3 Δ T\right)} {s}_{4} {i}_{2}\right) \left({i}^{′} {\text{}}_{3} {i}_{1}\right) \left(- {i}^{′} {\text{}}_{1} {i}_{3}\right)\end{matrix}$$

Substitution for e^{τΔT}= x

$$\begin{matrix}{\text{d = e}}^{\text{τ} \left(i\right)} \left({s}_{4} {i}_{2} \left({i}^{′} {\text{}}_{3} {i}_{1} - {i}^{′} {\text{}}_{1} {i}_{3}\right) {x}^{3} - {s}_{3} {i}_{1} \left({i}^{′} {\text{}}_{4} {i}_{2} - {i}^{′} {\text{}}_{2} {i}_{4}\right)\right) {x}^{2} - {s}_{2} {i}_{4} \left({i}^{′} {\text{}}_{3} {i}_{1} - {i}^{′} {\text{}}_{1} {i}_{3}\right) {x}^{1} {\text{d=e}}^{\text{τ} \left(t\right)} \left({s}_{4} {i}_{2} \left({i}^{′} {\text{}}_{3} {i}_{1}\right)\right) \\ + {s}_{1} {i}_{3} \left(\left({i}^{′} {\text{}}_{4} {i}_{2} - {i}^{′} {\text{}}_{2} {i}_{4}\right)\right) \\ {U}_{\text{LB}} \text{=} \frac{\text{e}}{\text{d}} \\ = \frac{\left({u}_{4} {i}_{2} - {u}_{2} {i}_{4}\right) \left({i}^{′} {\text{}}_{3} {i}_{1} - {i}^{′} {\text{}}_{1} {i}_{3}\right) - \left({u}_{3} {i}_{1} - {u}_{1} {i}_{3}\right) \left({i}^{′} {\text{}}_{4} {i}_{2} - {i}^{′} {\text{}}_{2} {i}_{4}\right)}{{e}^{τ \left(t\right)} \left({s}_{4} {i}_{2} \left({i}^{′} {\text{}}_{3} {i}_{1} - {i}^{′} {\text{}}_{1} {i}_{3}\right) {x}^{3} - {s}_{3} {i}_{1} \left({i}^{′} {\text{}}_{4} {i}_{2} - {i}^{′} {\text{}}_{2} {i}_{4}\right) {x}^{2} - {s}_{2} {i}_{4} \left({i}^{′} {\text{}}_{3} {i}_{1} - {i}^{′} {\text{}}_{1} {i}_{3}\right) {x}^{1} + {s}_{1} {i}_{3} \left({i}^{′}\right)\right)}\end{matrix}$$

$$\begin{matrix}b = {e}^{\text{τ} \left(t\right)} \left({s}_{4} {i}_{3} \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right)\right) {x}^{2} - \\ {s}_{2} {i}_{1} \left({i}^{′} {\text{}}_{4} {i}_{3} - {i}^{′} {\text{}}_{3} {i}_{4}\right) x + {s}_{1} {i}_{2} \left({i}^{′} {\text{}}_{4} {i}_{3} - {i}^{′} {\text{}}_{3} {i}_{4}\right)\end{matrix}$$

$$\begin{matrix}{U}_{\text{LB}} = \frac{f}{b} \\ = \frac{\left({i}^{′} {\text{}}_{2} {i}_{1} - {i}^{′} {\text{}}_{1} {i}_{2}\right) \left({u}_{4} {i}_{3} - {u}_{3} {i}_{4}\right) - \left({i}^{′} {\text{}}_{4} {i}_{3} - {i}^{′} {\text{}}_{3} {i}_{4}\right) \left({u}_{2} {i}_{1} - {u}_{1} {i}_{2}\right)}{{e}^{\text{τ} \left(t\right)} \left({s}_{4} {i}_{3}\right) \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right) {x}^{2} - {s}_{2} {i}_{1} \left({i}^{′} {\text{}}_{4} {i}_{3} - {i}^{′} {\text{}}_{3} {i}_{4}\right) x + {s}_{1} {i}_{2} \left({i}^{′} {\text{}}_{4} {i}_{3}\right)}\end{matrix}$$

Equating U-LB

$$\begin{matrix}\frac{\left({i}^{′} {\text{}}_{2} {i}_{1} - {i}^{′} {\text{}}_{1} {i}_{2}\right) \left({u}_{4} {i}_{3} - {u}_{3} {i}_{4}\right) - \left({i}^{′} {\text{}}_{4} {i}_{3} - {i}^{′} {\text{}}_{3} {i}_{4}\right) \left({u}_{2} {i}_{1} - {u}_{1} {i}_{2}\right)}{{e}^{\text{τ} \left(t\right)} \left({s}_{4} {i}_{3} \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right) {x}^{2} - {s}_{2} {i}_{1} \left({i}^{′} {\text{}}_{4} {i}_{3} - {i}^{′} {\text{}}_{3} {i}_{4}\right) x + {s}_{1} {i}_{2} \left({i}^{′} {\text{}}_{4} {i}_{3} -\right)\right)} \\ = \frac{\left({u}_{4} {i}_{2} - {u}_{2} {i}_{4}\right) \left({i}^{′} {\text{}}_{3} {i}_{1} - {i}^{′} {\text{}}_{1} {i}_{3}\right) - \left({u}_{3} {i}_{1} - {u}_{1} {i}_{3}\right) \left({i}^{′} {\text{}}_{4} {i}_{2} - {i}^{′} {\text{}}_{2} {i}_{4}\right)}{{e}^{\text{τ} \left(t\right)} \left({s}_{4} {i}_{2}\right) \left({i}^{′} {\text{}}_{3} {i}_{1} - {i}^{′} {\text{}}_{1} {i}_{3}\right) {x}^{3} - {s}_{3} {i}_{1} \left({i}^{′} {\text{}}_{4} {i}_{2} - {i}^{′} {\text{}}_{2} {i}_{4}\right) {x}^{2} - {s}_{2} {i}_{4} \left({i}^{′} {\text{}}_{3} {i}_{1} - {i}^{′} {\text{}}_{1} {i}_{3}\right) {x}^{1} + {s}_{1} {i}_{3} \left({i}^{′} {\text{}}_{4}\right)}\end{matrix}$$

$$\begin{matrix}\frac{{e}^{\text{τ} \left(t\right)} \left({s}_{4} {i}_{2} \left({i}^{′} {\text{}}_{3} {i}_{1} - {i}^{′} {\text{}}_{1} {i}_{3}\right) {x}^{3} - {s}_{3} {i}_{1} \left({i}^{′} {\text{}}_{4} {i}_{2} - {i}^{′} {\text{}}_{2} {i}_{4}\right) {x}^{2} - {s}_{2} {i}_{4} \left({i}^{′} {\text{}}_{3} {i}_{1} - {i}^{′} {\text{}}_{1} {i}_{3}\right) {x}^{1} + {s}_{1} {i}_{3} \left({i}^{′} {\text{}}_{4} {i}_{2}\right)\right)}{{e}^{\text{τ} \left(t\right)} \left({s}_{4} {i}_{3} \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right) {x}^{2} - {s}_{2} {i}_{1} \left({i}^{′} {\text{}}_{4} {i}_{3} - {i}^{′} {\text{}}_{3} {i}_{4}\right) x + {s}_{1} {i}_{3} \left({i}^{′} {\text{}}_{4} {i}_{3}\right) -\right)} \\ = \frac{\left({u}_{4} {i}_{2} - {u}_{2} {i}_{4}\right) \left({i}^{′} {\text{}}_{3} {i}_{1} - {i}^{′} {\text{}}_{1} {i}_{3}\right) - \left({u}_{3} {i}_{1} - {u}_{1} {i}_{3}\right) \left({i}^{′} {\text{}}_{4} {i}_{2} - {i}^{′} {\text{}}_{2} {i}_{4}\right)}{\left({i}^{′} {\text{}}_{2} {i}_{1} - {i}^{′} {\text{}}_{1} {i}_{2}\right) \left({u}_{4} {i}_{3} - {u}_{3} {i}_{4}\right) - \left({i}^{′} {\text{}}_{4} {i}_{3} - {i}^{′} {\text{}}_{3} {i}_{4}\right) \left({u}_{2} {i}_{1} - {u}_{1} {i}_{2}\right)}\end{matrix}$$

$$\begin{matrix}\frac{\left({s}_{4} {i}_{2} \left({i}^{′} {\text{}}_{3} {i}_{1} - {i}^{′} {\text{}}_{1} {i}_{3}\right) {x}^{3} - {s}_{3} {i}_{1} \left({i}^{′} {\text{}}_{4} {i}_{2} - {i}^{′} {\text{}}_{2} {i}_{4}\right) {x}^{2}\right) - {s}_{2} {i}_{4} \left({i}^{′} {\text{}}_{3} {i}_{1} - {i}^{′} {\text{}}_{1} {i}_{3}\right) x + {s}_{1} {i}_{3} \left({i}^{′} {\text{}}_{4} {i}_{2} - {i}^{′} {\text{}}_{2} i\right)}{\left({s}_{4} {i}_{3} \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right) {x}^{2} - {s}_{2} {i}_{1} \left({i}^{′} {\text{}}_{4} {i}_{3} - {i}^{′} {\text{}}_{3} {i}_{4}\right) x + {s}_{1} {i}_{2} \left({i}^{′} {\text{}}_{4} {i}_{3} - {i}^{′} {\text{}}_{3} i\right)\right)} \\ = \frac{\left({u}_{4} {i}_{2} - {u}_{2} {i}_{4}\right) \left({i}^{′} {\text{}}_{3} {i}_{1} - {i}^{′} {\text{}}_{1} {i}_{3}\right) - \left({u}_{3} {i}_{1} - {u}_{1} {i}_{3}\right) \left({i}^{′} {\text{}}_{4} {i}_{2} - {i}^{′} {\text{}}_{2} {i}_{4}\right)}{\left({i}^{′} {\text{}}_{2} {i}_{1} - {i}^{′} {\text{}}_{1} {i}_{2}\right) \left({u}_{4} {i}_{3} - {u}_{3} {i}_{4}\right) - \left({i}^{′} {\text{}}_{4} {i}_{3} - {i}^{′} {\text{}}_{3} {i}_{4}\right) \left({u}_{2} {i}_{1} - {u}_{1} {i}_{2}\right)}\end{matrix}$$

$$\begin{matrix}e = \left({u}_{4} {i}_{2} - {u}_{2} {i}_{4}\right) \left({i}^{′} {\text{}}_{3} {i}_{1} - {i}^{′} {\text{}}_{1} {i}_{3}\right) - \left({u}_{3} {i}_{1} - {u}_{1} {i}_{3}\right) \left({i}^{′} {\text{}}_{4} {i}_{2} - {i}^{′} {\text{}}_{2} {i}_{4}\right) \\ f = \left({i}^{′} {\text{}}_{2} {i}_{1} - {i}^{′} {\text{}}_{1} {i}_{2}\right) \left({u}_{4} {i}_{3} - {u}_{3} {i}_{4}\right) - \left({i}^{′} {\text{}}_{4} {i}_{3} - {i}^{′} {\text{}}_{3} {i}_{4}\right) \left({u}_{2} {i}_{1} - {u}_{1} {i}_{2}\right)\end{matrix}$$

$$\begin{matrix}f {s}_{4} {i}_{2} \left({i}^{′} {\text{}}_{3} {i}_{2} - {i}^{′} {\text{}}_{1} {i}_{3}\right) {x}^{3} - f {s}_{3} {i}_{1} \left({i}^{′} {\text{}}_{4} {i}_{2} - {i}^{′} {\text{}}_{2} {i}_{4}\right) {x}^{2} - f {s}_{2} {i}_{4} \left({i}^{′} {\text{}}_{3} {i}_{1} - {i}^{′} {\text{}}_{1} {i}_{3}\right) x \\ + f {s}_{1} {i}_{3} \left({i}^{′} {\text{}}_{4} {i}_{2} - {i}^{′} {\text{}}_{2} {i}_{4}\right) \\ = e {s}_{4} {i}_{3} \left({i}^{′} {\text{}}_{2} {i}_{1} - {i}^{′} {\text{}}_{1} {i}_{2}\right) {x}^{3} - e {s}_{3} {i}_{4} \left({i}^{′} {\text{}}_{2} {i}_{1} - {i}^{′} {\text{}}_{1} {i}_{2}\right) {x}^{2} - e {s}_{2} {i}_{1} \left({i}^{′} {\text{}}_{4} {i}_{3} - {i}^{′} {\text{}}_{3} {i}_{4}\right) x \\ + e {s}_{1} {i}_{2} \left({i}^{′} {\text{}}_{4} {i}_{3} {i}^{′} {\text{}}_{3} {i}_{4}\right)\end{matrix}$$

$$\begin{matrix}f {s}_{4} {i}_{2} \left({i}^{′} {\text{}}_{3} {i}_{1} - {i}^{′} {\text{}}_{1} {i}_{3}\right) {x}^{3} - f {s}_{3} {i}_{1} \left({i}^{′} {\text{}}_{4} {i}_{2} - {i}^{′} {\text{}}_{2} {i}_{4}\right) {x}^{2} - f {s}_{2} {i}_{4} \left({i}^{′} {\text{}}_{3} {i}_{1} - {i}^{′} {\text{}}_{1} {i}_{3}\right) x + \\ f {s}_{1} {i}_{3} \left({i}^{′} {\text{}}_{4} {i}_{2} - {i}^{′} {\text{}}_{2} {i}_{4}\right) \\ = e {s}_{4} {i}_{3} \left({i}^{′} {\text{}}_{2} {i}_{1} - {i}^{′} {\text{}}_{1} {i}_{2}\right) {x}^{3} - e {s}_{3} {i}_{4} \left({i}^{′} {\text{}}_{2} {i}_{1} - {i}^{′} {\text{}}_{1} {i}_{2}\right) {x}^{2} - e {s}_{2} {i}_{1} \left({i}^{′} {\text{}}_{4} {i}_{3} - {i}^{′} {\text{}}_{3} {i}_{4}\right) x \\ + e {s}_{1} {i}_{2} \left({i}^{′} {\text{}}_{4} {i}_{3} - {i}^{′} {\text{}}_{3} {i}_{4}\right)\end{matrix}$$

$$\begin{matrix}\left(\left(f {s}_{4} {i}_{2} \left({i}^{′} {\text{}}_{3} {i}_{1} - {i}^{′} {\text{}}_{1} {i}_{3}\right)\right) - e {s}_{4} {i}_{3} \left({i}^{′} {\text{}}_{2} {i}_{1} - {i}^{′} {\text{}}_{1} {i}_{2}\right)\right) {x}^{3} + \left(e {s}_{3} {i}_{4} \left({i}^{′} {\text{}}_{2} {i}_{1} - {i}^{′} {\text{}}_{1} {i}_{2}\right)\right) \\ - f {s}_{3} {i}_{1} \left({i}^{′} {\text{}}_{4} {i}_{2} -\right) \left(\left({i}^{′} {\text{}}_{2} {i}_{4}\right)\right) {x}^{2} + \left(e {s}_{2} {i}_{1} \left({i}^{′} {\text{}}_{4} {i}_{3} - {i}^{′} {\text{}}_{3} {i}_{4}\right) - f {s}_{2} {i}_{4} \left(\left({i}^{′} {\text{}}_{3} {i}_{1} - {i}^{′} {\text{}}_{1} {i}_{3}\right)\right)\right) x \\ + \left(f {s}_{1} {i}_{3} \left({i}^{′} {\text{}}_{4} {i}_{2} - {i}^{′} {\text{}}_{2} {i}_{4}\right) -\right) e {s}_{1} {i}_{2} \left(\left({i}^{′} {\text{}}_{4} {i}_{3} - {i}^{′} {\text{}}_{3} {i}_{4}\right)\right) = 0\end{matrix}$$

$$\begin{matrix}{i}_{31} = {i}^{′} {\text{}}_{3} {i}_{1} - {i}^{′} {\text{}}_{1} {i}_{3} \\ {\text{i}}_{42} = {i}^{′} {\text{}}_{4} {i}_{2} - {i}^{′} {\text{}}_{2} {i}_{4} \\ {i}_{21} = {i}^{′} {\text{}}_{2} {i}_{1} - {i}^{′} {\text{}}_{1} {i}_{2} \\ {i}_{43} = {i}^{′} {\text{}}_{4} {i}_{3} - {i}^{′} {\text{}}_{3} {i}_{4}\end{matrix}$$

$$\begin{matrix}{s}_{4} \left(f {i}_{2} {i}_{31} - e {i}_{3} {i}_{21}\right) {x}^{3} + {s}_{3} \left(e {i}_{4} {i}_{21} - f {i}_{1} {\text{i}}_{42}\right) {x}^{2} + {s}_{2} \left(e {i}_{1} {i}_{43} - f {i}_{4} {i}_{31}\right) x + {s}_{1} \\ \left(f {i}_{3} {\text{i}}_{42} -\right) \left(e {i}_{2} {i}_{43}\right) = 0\end{matrix}$$

$$\begin{matrix}x 3 = {s}_{4} \left(f {i}_{2} {i}_{31} - e {i}_{3} {i}_{21}\right) \\ x 2 = {s}_{3} \left(e {i}_{4} {i}_{21} - f {i}_{1} {\text{i}}_{42}\right)\end{matrix}$$

$$\begin{matrix}\text{x} 1 = {s}_{2} \left(e {i}_{1} {i}_{43} - f {i}_{4} {i}_{31}\right) \\ x 0 = {s}_{1} \left(f {i}_{3} {\text{i}}_{42} - e {i}_{2} {i}_{43}\right) \\ x 3 {x}^{3} + x 2 {x}^{2} + x 1 {x}^{1} + x 0 = 0\end{matrix}$$

Calculation of the arc voltage

$$\begin{matrix}{U}_{\text{LB}} = \frac{f}{b} \\ = \frac{f}{{e}^{\text{τ} \left(t\right)} \left(\left({s}_{4} {i}_{3} \left({i}^{′} {\text{}}_{2} {i}_{1} - {i}^{′} {\text{}}_{1} {i}_{2}\right) {x}^{3} - {s}_{3} {i}_{4} \left({i}^{′} {\text{}}_{2} {i}_{1} - {i}^{′} {\text{}}_{1} {i}_{2}\right) {x}^{2}\right)\right)} \\ \frac{}{- {s}_{2} {i}_{1} \left({i}^{′} {\text{}}_{4} {i}_{3} - {i}^{′} {\text{}}_{3} {i}_{4}\right) x + {s}_{1} {i}_{2} \left(\left({i}^{′} {\text{}}_{4} {i}_{3} - {i}^{′} {\text{}}_{3} {i}_{4}\right)\right)}\end{matrix}$$

$${U}_{\text{LB}} = \frac{f}{{e}^{\text{τ} \left(t\right)} \left({s}_{4} {i}_{3} {i}_{21} {x}^{3} - {s}_{3} {i}_{4} {i}_{21} {x}^{2} - {s}_{2} {i}_{1} {i}_{43} x + {s}_{1} {i}_{2} {i}_{43}\right)}$$

Although the invention has been more specifically illustrated and described in detail by means of the exemplary embodiment, nevertheless the invention is not restricted by the examples disclosed and other variations can be derived therefrom by the person skilled in the art, without departing from the scope of protection of the invention.

1-19. (canceled)

20. An arrangement for detecting arcs in a low-voltage circuit, the arrangement comprising:
at least one voltage sensor for periodically determining voltage values of the low-voltage circuit;
at least one current sensor for periodically determining current values of the low-voltage circuit; and
a first control unit connected to said at least one voltage sensor and said at least one current sensor, said first control unit having a processor and being configured to determine from the voltage values determined by said at least one voltage sensor and the current values determined by said at least one current sensor whether a switching arc is present and, if a switching arc is determined to be present, to output a switching arc detection signal.

21. The arrangement according to claim 20, wherein the voltage values and current values are used for determining an exponential function and said control unit is configured to output the switching arc detection signal only if an exponent of the exponential function lies within a given range.

22. The arrangement according to claim 21, wherein aid control unit is configured to output the switching arc detection signal only if a change in the voltage over time exceeds a first jump limit value or if a voltage jump is detected.

23. The arrangement according to claim 22, wherein the control unit is configured to begin a determination of the exponential function when the first jump limit value or the voltage jump is exceeded.

24. The arrangement according to claim 21, configured to:
determine a voltage value and a current value as a value pair within a first time window;
determine an arc voltage and an exponent from at least four successively determined value pairs; and
output a switching arc detection signal when the arc voltage exceeds an arc voltage limit value and the exponent lies within the given range.

25. The arrangement according to claim 21, wherein:
a change in the current over time is determined as a change value from the determined current value;
the voltage value, the current value, and the change value of a time window form a value set;
an arc voltage and the exponent are determined from at least four successively determined value sets; and
the switching arc detection signal is output if the arc voltage exceeds an arc voltage limit value and the exponent lies within the given range.

26. The arrangement according to claim 20, further comprising a second control unit, and wherein said second control unit or said first control unit is configured to determine the presence of an arc fault from the voltage values and the current values and to output an arc fault detection signal if the arc fault is determined to present.

27. The arrangement according to claim 26, further comprising an interruption unit for interrupting the low-voltage circuit, wherein said interruption unit is connected to said first control unit and optionally to said second control unit, and wherein the low-voltage circuit is interrupted in case of a positive determination of an arc fault and a negative determination of a switching arc.

28. The arrangement according to claim 27, wherein an interruption takes place only if a given number of current values exceed a given current limit value.

29. The arrangement according to claim 28, wherein the low-voltage circuit is a low-voltage AC circuit.

30. A low-voltage circuit breaker, comprising an arrangement according to claim 20.

31. A method for determining an arc in a low-voltage circuit, the method comprising:
periodically determining voltage values and current values of the low-voltage circuit;
using the voltage values and current values for determining an exponent of an exponential function; and
outputting a switching arc detection signal only if the exponent lies within a given range.

32. The method according to claim 31, which comprises outputting the switching arc detection signal only if a change in the voltage over time exceeds a first jump limit value or a voltage jump is determined to lie within a lower and an upper bound.

33. The method according to claim 32, which comprises initiating the step of determining the exponent of the exponential function upon the first jump limit value being exceeded or the voltage jump being detected.

34. The method according to claim 31, which comprises determining a voltage value and a current value as a value pair within a given time window, and determining the exponent from at least four successively determined value pairs.

35. The method according to claim 34, which comprises determining the voltage value and the current value of the value pair simultaneously.

36. The method according to claim 34, which comprises:
determining a change in the current over time as a change value from determined current values;
forming a value set with the voltage value, the current value, and the change value of a time window; and
determining the exponent from at least four successively determined value sets.

37. The method according to claim 31, which comprises determining a presence of an arc fault from the voltage values and the current values and, upon determining an arc fault, outputting an arc fault detection signal.

38. The method according to claim 37, which comprises carrying out an interruption of the low-voltage circuit in the case of a positive determination of an arc fault and a negative determination of a switching arc.

39. The method according to claim 38, which comprises interrupting the low-voltage circuit only if a number of current values exceed a given current limit value.
